(19) United States
(12) Patent Application Publication
(10) Pub. No.: US 2011/0101467 A1
(43) Pub. Date: May 5, 2011

(54) STACKED SEMICONDUCTOR DEVICE AND METHOD OF MANUFACTURING THE SAME

(75) Inventors: Kyung-Tae Jang, Seoul (KR); Ju-Bum Lee, Hwaseong-si (KR); Jae-Kyo Chung, Suwon-si (KR); Heung-Seop Song, Seoul (KR); Mi-Young Lee, Seoul (KR)

(73) Assignee: SAMSUNG ELECTRONICS CO., LTD., Suwon-si (KR)

(21) Appl. No.: 12/986,739

(22) Filed: Jan. 7, 2011

Related U.S. Application Data
(62) Division of application No. 11/978,330, filed on Oct. 29, 2007.

(30) Foreign Application Priority Data
Nov. 10, 2006 (KR) 10-2006-0110918

(51) Int. Cl. H01L 27/088

(52) U.S. Cl. 257/392; 257/E27.06

(57) ABSTRACT

A stacked semiconductor device includes a first gate structure formed on a substrate, a first insulating interlayer covering the first gate structure on the substrate, a first active pattern formed through and on the first insulating interlayer and contacting the substrate, a second gate structure formed on the first active pattern and the first insulating interlayer, a buffer layer covering the second gate structure on the first active pattern and the first insulating interlayer, a second insulating interlayer formed on the buffer layer, and a contact plug formed through the first and second insulating interlayers, which contacts with the substrate and is insulated from the second gate structure by the buffer layer. Operation failures of a transistor in the stacked semiconductor device can be reduced because the buffer layer prevents a word line from being electrically connected to the contact plug.

### CROSS-REFERENCE TO RELATED APPLICATIONS

This application is a divisional application of U.S. patent application Ser. No. 11/978,330, filed on Oct. 29, 2007, which claims priority to Korean Patent Application No. 10-2006-0110918, filed on Nov. 10, 2006, in the Korean Intellectual Property Office, the contents of which applications are incorporated herein in their entirety by reference.

### BACKGROUND OF THE INVENTION

1. Field of the Invention

The present invention relates to a stacked semiconductor device and a method of manufacturing the same. More particularly, the present invention relates to a stacked semiconductor device in which a plurality of unit elements, such as a transistor having a gate structure and a source/drain region, is formed in a plurality of layers and a method of manufacturing the same.

2. Description of the Related Art

Sizes of unit elements and spaces between the unit elements have been reduced in order to realize a high integration degree in a semiconductor device. However, there have been technical difficulties in reducing the sizes of the unit elements and the spaces between the unit elements in semiconductor devices.

Thus, a stacked semiconductor device in which a plurality of unit elements is formed in a plurality of layers has been recently developed. For example, a stacked semiconductor device having such a stacked structure is disclosed in U.S. Pat. No. 6,538,330. The stacked semiconductor device is commonly employed in a static random access memory (SRAM) device, a system on chip (SOC), and other similar devices known in the art.

A stacked SRAM device includes a unit cell having two drive transistors, two load transistors and two access transistors, and the transistors are formed in a plurality of layers. A plurality of active layers is formed on a plurality of insulating interlayers, respectively, because the transistors are formed in the plurality of layers. The active layers are usually formed by a selective epitaxial growth (SEG) process in which a portion of a semiconductor substrate exposed by an opening formed through the insulating interlayer(s) is used as a seed layer. Each of the active layers is patterned to form an active pattern, and a region of the stacked SRAM device in which the active pattern is formed can be referred to as an active region and a region of the stacked SRAM device in which the active pattern is not formed can be referred to as a field region.

A stacked SRAM device having a triple-layered structure includes two drive transistors, two load transistors and two access transistors that are sequentially stacked on a substrate, a first active pattern and a second active pattern, respectively. Each of the transistors contains a gate structure and a source/drain region formed in an active region of the stacked SRAM device. The gate structure of the access transistor has a linear shape and is used as a word line, thereby being formed not only in the active region but also in a field region. Thus, the gate structure is formed not only on the second active pattern but also on a portion of an insulating interlayer in which the second active pattern is not formed.

A length of a channel region in an active pattern is important characteristic of a semiconductor device. The channel region is formed at an upper portion of the active pattern covered by a gate structure so that a shape of the gate structure can have influence on the length of the channel region. Thus, when the gate structure is formed by patterning a gate insulation layer and a gate conductive layer after forming the gate insulation layer and the gate conductive layer on the active pattern and the insulating interlayer, the gate insulation layer and the gate conductive layer are patterned so that a portion of the gate structure formed on the active pattern can have a vertical profile and the channel region can have a predetermined length. Thus, portions of the gate insulation layer and the gate conductive layer formed on the insulating interlayer on which the active pattern is not formed are usually over-etched such that the portion of the gate structure formed on the active pattern can have the vertical profile. Accordingly, voids can be formed near the over-etched portions when an insulating interlayer is formed to cover the access transistor. In that case, when a contact plug for electrically connecting the transistors formed in a plurality of layers is formed, a metal included in the contact plug can move to the voids and degenerate insulation characteristics between the word line and the contact plug. As a result, failures of operations of the transistors can be generated and reliabilities of the semiconductor device including the transistors can be lowered.

### SUMMARY OF THE INVENTION

In accordance with aspects of the present invention, there is provided a stacked semiconductor device having improved insulation characteristics between a word line and a contact plug.

Also in accordance with aspects of the present invention, there is provided a method of manufacturing a stacked semiconductor device having improved insulation characteristics between a word line and a contact plug.

According to one aspect of the present invention, there is provided a stacked semiconductor device. The stacked semiconductor device includes a first gate structure, a first insulating interlayer, a first active pattern, a second gate structure, a buffer layer, a second insulating interlayer, and a contact plug. The first gate structure is formed on a substrate. The first insulating interlayer covers the first gate structure on the substrate. The first active pattern is formed through and on the first insulating interlayer, and makes contact with the substrate. The second gate structure is formed on the first active pattern and the first insulating interlayer. The buffer layer covers the second gate structure on the first active pattern and the first insulating interlayer. The second insulating interlayer is formed on the buffer layer. The contact plug is formed through the first and second insulating interlayers and makes contact with the substrate. The contact plug is insulated from the second gate structure by the buffer layer.

The second gate structure can include a third gate structure on the first active pattern and a fourth gate structure on the first insulating interlayer.

The third and fourth gate structures can be connected to form a word line.

The third gate structure can have a substantially vertical profile with respect to the first active pattern, and the fourth gate structure can have a lower portion narrower than an upper portion thereof.

The first gate structure can include a first gate insulation layer pattern and a first gate electrode, and the second gate structure can include a second gate insulation layer pattern and a second gate electrode.

The substrate can include an active region having a first source/drain region and a field region. The first active pattern can make contact with the first source/drain region.

The first active pattern can include a second source/drain region, and the contact plug can be electrically connected to the first and second source/drain regions.

The buffer layer can include SOG, USG, HDP-CVD oxide, ALD oxide or MTO oxide.

The stacked semiconductor device can further include a protection layer formed between the first active pattern and the first insulating interlayer. The protection layer can be configured to prevent damage to the first active pattern.

The substrate can include silicon and the first active pattern can include single crystalline silicon.

According to another aspect of the present invention, there is provided a stacked semiconductor device. The stacked semiconductor device includes a first gate structure, a first insulating interlayer, a first active pattern, a second gate structure, a second insulating interlayer, a second active pattern, a third gate structure, a buffer layer, a third insulating interlayer, and a contact plug. The first gate structure is formed on a substrate. The first insulating interlayer covers the first gate structure on the substrate. The first active pattern is formed through and on the first insulating interlayer, and makes contact with the substrate. The second gate structure is formed on the first active pattern. The second insulating interlayer covers the second gate structure on the first active pattern and the first insulating interlayer. The second active pattern is formed through and on the second insulating interlayer, and makes contact with the first active pattern. The third gate structure is formed on the second active pattern and the second insulating interlayer. The buffer layer covers the third gate structure on the second active pattern and the second insulating interlayer. The third insulating interlayer is formed on the buffer layer. The contact plug is formed through the first to third insulating interlayers and makes contact with the substrate. The contact plug is insulated from the third gate structure by the buffer layer.

The third gate structure can include a fourth gate structure on the second active pattern and a fifth gate structure on the second insulating interlayer, and the fourth and fifth gate structures can be connected to form a word line.

The fourth gate structure can have a substantially vertical profile with respect to the second active pattern, and the fifth gate structure can have a lower portion narrower than an upper portion thereof.

The substrate can include an active region having a first source/drain region and a field region. The first and second active patterns can include second and third source/drain regions, respectively. The contact plug can be electrically connected to the first to third source/drain regions.

The first gate structure and the first source/drain region can form a drive transistor, the second gate structure and the second source/drain region can form a load transistor, and the third gate structure and the third source/drain region can form an access transistor.

According to still another aspect of the present invention, there is provided a method of manufacturing a stacked semiconductor device. In the method of manufacturing the stacked semiconductor device, a first gate structure is formed on a substrate. A first insulating interlayer is formed on the substrate to cover the first gate structure. A first opening exposing the substrate is formed through the first insulating interlayer. A first active pattern filling the first opening is formed on the substrate and the first insulating interlayer. A second gate structure is formed on the first active pattern and the first insulating interlayer. A buffer layer is formed on the first active pattern and the first insulating interlayer to cover the second gate structure. A second insulating interlayer is formed on the buffer layer. A second opening exposing the substrate is formed through the first and second insulating interlayers. A contact plug filling the second opening is formed on the substrate.

When the second gate structure is formed, a gate insulation layer and a gate conductive layer can be sequentially formed on the first active pattern and the first insulating interlayer. The gate insulation layer and the gate conductive layer can be patterned to form a third gate structure including a first gate insulation layer pattern and a first gate electrode sequentially formed on the first active pattern and to form a fourth gate structure including a second gate insulation layer pattern and a second gate electrode sequentially formed on the first insulating interlayer.

The third gate structure can be patterned to have a substantially vertical profile with respect to the first active pattern.

When the first active pattern is formed, an active layer filling the first opening can be formed on the substrate and the first insulating interlayer by a SEG process using the substrate as a seed layer. The active pattern can be patterned.

A first source/drain region can be further formed at an upper portion of the substrate and a second source/drain region can be further formed at an upper portion of the first active pattern.

When the second opening is formed, the second opening can be formed through the first and second source/drain regions.

The buffer layer can include SOG, USG, HDP-CVD oxide, ALD oxide or MTO oxide.

Before the buffer layer is formed, a protection layer can be further formed on the second gate structure, the first active pattern and the first insulating interlayer to reduce damages of the second gate structure.

The substrate can include silicon and the first active pattern can include single crystalline silicon.

According to still another aspect of the present invention, there is provided a method of manufacturing a stacked semiconductor device. In the method of manufacturing the stacked semiconductor device, a first gate structure is formed on a substrate. A first insulating interlayer is formed on the substrate to cover the first gate structure. A first opening exposing the substrate is formed through the first insulating interlayer. A first active pattern filling the first opening is formed on the substrate and the first insulating interlayer. A second gate structure is formed on the first active pattern. A second insulating interlayer is formed on the first active pattern and the first insulating interlayer to cover the second gate structure. A second opening exposing the first active pattern is formed through the second insulating interlayer. A second active pattern filling the second opening is formed on the first active pattern and the second insulating interlayer. A third gate structure is formed on the second active pattern and the second insulating interlayer. A buffer layer is formed on the second active pattern and the second insulating interlayer to cover the third gate structure. A third insulating interlayer is formed on the buffer layer. A third opening exposing the substrate is formed through the first to third insulating interlayers. A contact plug filling the third opening is formed on the substrate.

When the third gate structure is formed, a gate insulation layer and a gate conductive layer can be sequentially formed on the second active pattern and the second insulating interlayer. The gate insulation layer and the gate conductive layer can be patterned to form a fourth gate structure including a first gate insulation layer pattern and a first gate electrode sequentially formed on the second active pattern and to form a fifth gate structure including a second gate insulation layer pattern and a second gate electrode sequentially formed on the second insulating interlayer.

The fourth gate structure can be patterned to have a substantially vertical profile with respect to the second active pattern.

A first source/drain region can be further formed at an upper portion of the substrate. A second source/drain region can be further formed at an upper portion of the first active pattern. A third source/drain region can be further formed at an upper portion of the second active pattern.

When the third opening is formed, the third opening can be formed through the first to third source/drain regions.

The buffer layer can include SOG, USG, HDP-CVD oxide, ALD oxide or MTO oxide.

According to some aspects of the present invention, a buffer layer is formed on a gate structure serving as a word line in a stacked semiconductor device, so that voids generated near a lower portion of the gate structure having been over-etched on a field region because of the height difference between an active region and the field region can be reduced or prevented. Additionally, a metal included in a contact plug electrically connecting transistors formed in a plurality of layers can be prevented from moving to the voids so that insulation characteristics between the contact plug and the word line can not be degenerated.

### BRIEF DESCRIPTION OF THE DRAWINGS

The above and other features and advantages of the present invention will become more apparent by describing, in detail, example embodiments in accordance with aspects thereof with reference to the accompanying drawings, in which:

FIG. 1 is a cross-sectional view illustrating an embodiment of a stacked semiconductor device in accordance with aspects of the present invention; and

FIGS. 2A to 2R are cross-sectional views illustrating an embodiment of a method of manufacturing a stacked semiconductor device in accordance with aspects of the present invention.

### DESCRIPTION OF THE EMBODIMENTS

Hereinafter, aspects of the present invention will be described by explaining illustrative embodiments in accordance therewith, with reference to the attached drawings. The present invention can, however, be embodied in many different forms and should not be construed as limited to the example embodiments set forth herein. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers can be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third and other similar material known in the art. can be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, can be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device can be otherwise oriented (rotated 90 degrees or at other orientations) and the spatially relative descriptors used herein interpreted accordingly.

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the invention are described herein with reference to cross-sectional illustrations that are schematic illustrations of idealized example embodiments (and intermediate structures) in accordance with the present invention. As such, variations from the shapes of the illustrations as a result, for example, of manufacturing techniques and/or tolerances, are to be expected. Thus, example embodiments should not be construed as limited to the particular shapes of regions illustrated herein, but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation can result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Hereinafter, example embodiments in accordance with aspects of the present invention will be explained in detail with reference to the accompanying drawings.

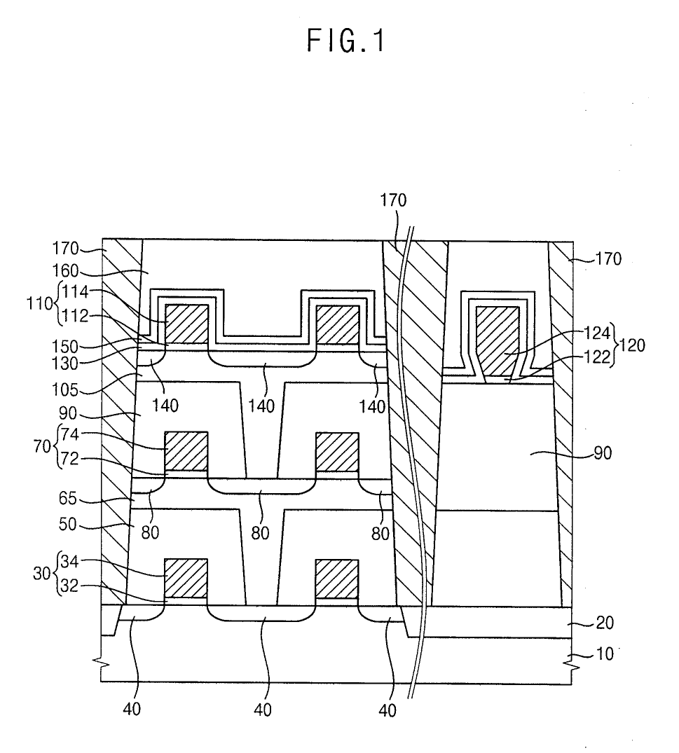

FIG. 1 is a cross-sectional view illustrating an example embodiment of a stacked semiconductor device in accordance with an aspect of the present invention.

Referring to FIG. 1, the stacked semiconductor device includes first through third transistors, first, second and third insulating interlayers 50, 90, 160, and a contact plug 170 on a substrate 10.

In an example embodiment, the first through third transistors are formed in three layers, and each of the transistors can serve as a drive transistor, a load transistor, and an access transistor, respectively.

The substrate 10 can include a silicon substrate, a silicon-on-insulator (SOI) substrate, a germanium substrate, a germanium-on-insulator (GOI) substrate, a silicon-germanium substrate, and other similar material known in the art.

An isolation layer 20 is formed on the substrate 10, and defines a first active region and a first field region in the substrate 10. The isolation layer 20 can include spin-on-glass (SOG), undoped silicate glass (USG), high density plasma chemical vapor deposition (HDP-CVD) oxide, and other similar material known in the art.

A first gate structure 30 includes a first gate insulation layer pattern 32 and a first gate electrode 34 sequentially formed on the first active region of the substrate 10. The first gate insulation layer pattern 32 can include a metal oxide having a low equivalent oxide thickness (EOT) and low leakage current characteristics. For example, the first gate electrode can include polysilicon, a metal, a metal nitride, and other similar materials known in the art.

A first source/drain region 40 is formed at an upper portion of the substrate 10 adjacent to the first gate structure 30, and can include first impurities. In an example embodiment, the first impurities include elements in Group V of the periodic table, such as phosphorus, arsenic, and other such elements known in the art, and thus the first source/drain region 40 can be an N-type impurity region. Accordingly, the first transistor including the first gate structure 30 and the first source/drain region 40 can be an N-type metal oxide semiconductor (MOS) transistor. In an example embodiment, two first transistors are formed in a unit cell, and each of the two first transistors can serve as a drive transistor. A spacer (not shown) including a nitride such as silicon nitride can be further formed on a sidewall of the first gate structure 30. When the spacer is formed, the first source/drain region 40 can have a lightly doped drain (LDD) structure.

The first insulating interlayer 50 is formed on the substrate 10 to cover the first gate structure 30. The first insulating interlayer 50 can include boro-phophor silicate glass (BPSG), USG, SOG, and other similar materials known in the art.

A first active pattern 65 is formed on a portion of the substrate 10 and a portion of the first insulating interlayer 50. In an example embodiment, the first active pattern 65 partially covers the first source/drain region 40. The first active pattern 65 can serve as a second active region for the second transistor. The first active pattern 65 can include single crystalline silicon, single crystalline germanium, single crystalline silicon-germanium, and other similar materials known in the art, according to a material of the substrate 10.

A second gate structure 70 includes a second gate insulation layer pattern 72 and a second gate electrode 74 sequentially formed on the first active pattern 65. The second gate insulation layer pattern 72 can include a metal oxide having a low EOT and low leakage current characteristics. The second gate electrode 74 can include polysilicon, a metal, a metal nitride, and other similar materials known in the art. The second gate insulation layer pattern 72 and the second gate electrode 74 can include materials substantially the same as those of the first gate insulation layer pattern 32 and the first gate electrode 34, respectively. However, the second gate insulation layer pattern 72 and the second gate electrode 74 can include materials different from those of the first gate insulation layer pattern 32 and the first gate electrode 34, respectively.

A second source/drain region 80 is formed at a portion of the first active pattern 65 adjacent to the second gate structure 70, and can include second impurities. In an example embodiment, the second impurities include elements in Group III of the periodic table, such as boron, gallium, and other such elements known in the art, and thus the second source/drain region 80 can be a P-type impurity region. Accordingly, the second transistor including the second gate structure 70 and the second source/drain region 80 can be a P-type MOS transistor. In an example embodiment, two second transistors are formed in the unit cell, and each of the two second transistors can serve as a load transistor. A spacer (not shown) including a nitride such as silicon nitride can be further formed on a sidewall of the second gate structure 70. When the spacer is formed, the second source/drain region 80 can have an LDD structure. Additionally, when an ion implantation process is performed to form the second source/drain region 80, a protection layer (not shown) including an oxide can be formed on the second gate structure 70, the first active pattern 65 and the first insulating interlayer 50 to reduce damages of the first active pattern 65.

The second insulating interlayer 90 is formed on the first active pattern 65 and the first insulating interlayer 50 to cover the second gate structure 70. The second insulating interlayer 90 can include BPSG, USG, SOG, and other similar materials known in the art. The second insulating interlayer 90 can include a material substantially the same as or different from that of the first insulating interlayer 50.

A second active pattern 105 is formed on a portion of the first active pattern 65 and a portion of the second insulating interlayer 90. In an example embodiment of the present invention, the second active pattern 105 partially covers the second source/drain region 80. The second active pattern 105 can serve as a third active region for the third transistor. The second active pattern 105 can include single crystalline silicon, single crystalline germanium, single crystalline silicon-germanium, and other similar materials known in the art, according to the material of the substrate 10.

A third gate structure 110 includes a third gate insulation layer pattern 112 and a third gate electrode 114 sequentially formed on the second active pattern 105. The third gate insulation layer pattern 112 can include a metal oxide having a low EOT and low leakage current characteristics. The third gate electrode 114 can include polysilicon, a metal, a metal nitride, and other similar materials known in the art. The third gate insulation layer pattern 112 and the third gate electrode 114 can include materials substantially the same as those of the first and second gate insulation layer patterns 32 and 72 and the first and second gate electrodes 34 and 74, respectively. However, the third gate insulation layer pattern 112 and the third gate electrode 114 can include materials different from those of the first and second gate insulation layer patterns 32 and 72 and the first and second gate electrode 34 and 74, respectively. The third gate structure 110 has a profile substantially vertical to the second active pattern 105. Thus, a channel region formed at an upper portion of the second active pattern 105 covered by the third gate structure 110 can have a predetermined length that is not changed according to a location thereof.

A fourth gate structure 120 includes a fourth gate insulation layer pattern 122 and a fourth gate electrode 124 sequentially formed on the second insulating interlayer 90. The fourth gate structure 120 is connected to the third gate structure 110, and thus serves as a word line (not shown). Thus, the fourth gate insulation layer pattern 122 and the fourth gate electrode 124 can include materials substantially the same as those of the third gate insulation layer pattern 112 and the third gate electrode 114. Unlike the third gate structure 110, the fourth gate structure 120 need not have a vertical profile with respect to the second insulating interlayer 90. Particularly, the fourth gate structure 120 can have a lower portion having a width smaller than that of an upper portion. In an example embodiment, the fourth gate insulation layer pattern 122 has a thickness substantially the same as that of the third gate insulation layer pattern 112, however, the fourth gate electrode 124 has a thickness larger than that of the third gate electrode 114. Thus, the third and fourth gate structures 110 and 120 can have substantially the same thickness.

A third source/drain region 140 is formed at a portion of the second active pattern 105 adjacent to the third gate structure 110, and can include third impurities. In an example embodiment, the third impurities include elements in Group V of the periodic table, such as phosphorous, arsenic, and other such elements known in the art, and thus the third source/drain region 140 can be an N-type impurity region. Accordingly, the third transistor including the third gate structure 110 and the third source/drain region 140 can be an N-type MOS transistor. In an example embodiment, two third transistors are formed in the unit cell, and each of the two third transistors can serve as an access transistor.

A protection layer 130 is formed on the third and fourth gate structures 110 and 120, the second active pattern 105, and the second insulating interlayer 90. The protection layer 130 can reduce damage to the second active pattern 105 generated when an ion implantation process for forming the third source/drain region 140 is performed. In an example embodiment, the protection layer 130 includes an oxide, and has a thickness of about 100 Å. Additionally, a portion of the third impurities included in the third source/drain region 140 can be trapped in the protection layer 130. A gate oxide layer (not shown) can be further formed between the protection layer 130 and the third and fourth gate structures 110 and 120, the second active pattern 105 and the second insulating interlayer 90, thereby curing the damages of the second active pattern 105 generated when the third gate structure 110 is formed.

A buffer layer 150 is formed on the protection layer 130. The buffer layer 150 can include SOG, USG, HDP-CVD oxide, and other similar materials known in the art. Alternatively, the buffer layer 150 can include an oxide having good insulation characteristics, such as atomic layer deposition (ALD) oxide, a middle temperature oxide (MTO), and other similar materials known in the art. In an example embodiment, the buffer layer 150 has a thickness of about 300 Å to about 1000 Å.

The buffer layer 150 formed on the protection layer 130 can prevent the portion of the third impurities trapped in the protection layer 130 from diffusing outward. Additionally, when the third insulating interlayer 160 covering the fourth gate structure 120 is formed, void generation near a lower portion of the fourth gate structure 120 can be reduced or prevented. Furthermore, when the contact plug 170 is formed, a metal included in the contact plug 170 can be prevented from moving to the void and making contact with the protection layer 130, so that degeneration of electrical insulation characteristics between the contact plug 170 and the fourth gate structure 120 can be prevented.

The third insulating interlayer 160 is formed on the buffer layer 150. The third insulating interlayer 160 can include BPSG, USG, SOG, and other similar materials known in the art. The third insulating interlayer 160 can include a material substantially the same as that of the first and second insulating interlayers 50 and 90. Alternatively, the third insulating interlayer 160 can include a material different from that of the first and second insulating interlayers 50 and 60.

The contact plug 170 partially covers the substrate 10. In an example embodiment, the contact plug 170 covers a portion of the first source/drain region 40 and a portion of the isolation layer 20. The contact plug 170 is formed through the first to third insulating interlayers 50, 90 and 160, the buffer layer 150, the protection layer 130 and the first and second active patterns 65 and 105. The contact plug 170 can include a material having good gap-filling characteristics, such as tungsten.

In an example embodiment, each of the first through third source/drain regions 40, 80 and 140 is electrically connected to the contact plug 170, thereby being electrically connected to one another. Particularly, the first and second drain regions and the third source region can be electrically connected to one another.

Until now, the stacked semiconductor device having the triple-layered structure has been illustrated; however, any stacked semiconductor devices having a multi-layered structure can be included within the scope of the present invention. That is, when a transistor including a gate structure, which is extended in a direction and forms a word line, is formed on an active pattern and an insulating interlayer, voids can be generated near a lower portion of the gate structure because of the height difference between the active pattern and the insulating interlayer. In that case, any stacked semiconductor device having a protection layer covering the gate structure can be included within the scope of the present invention.

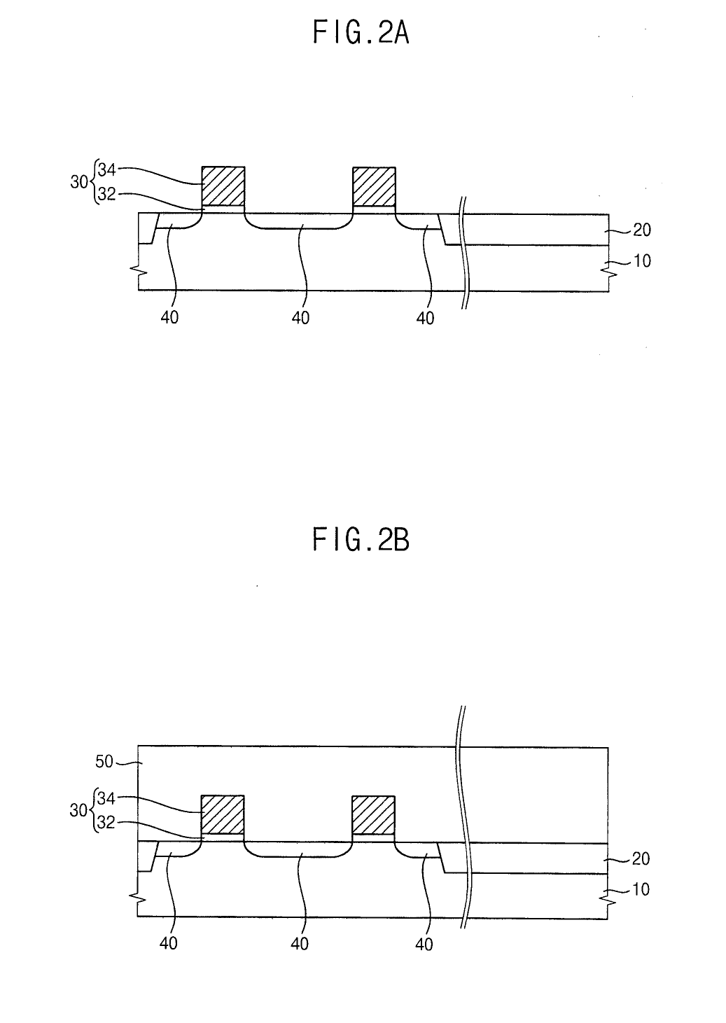

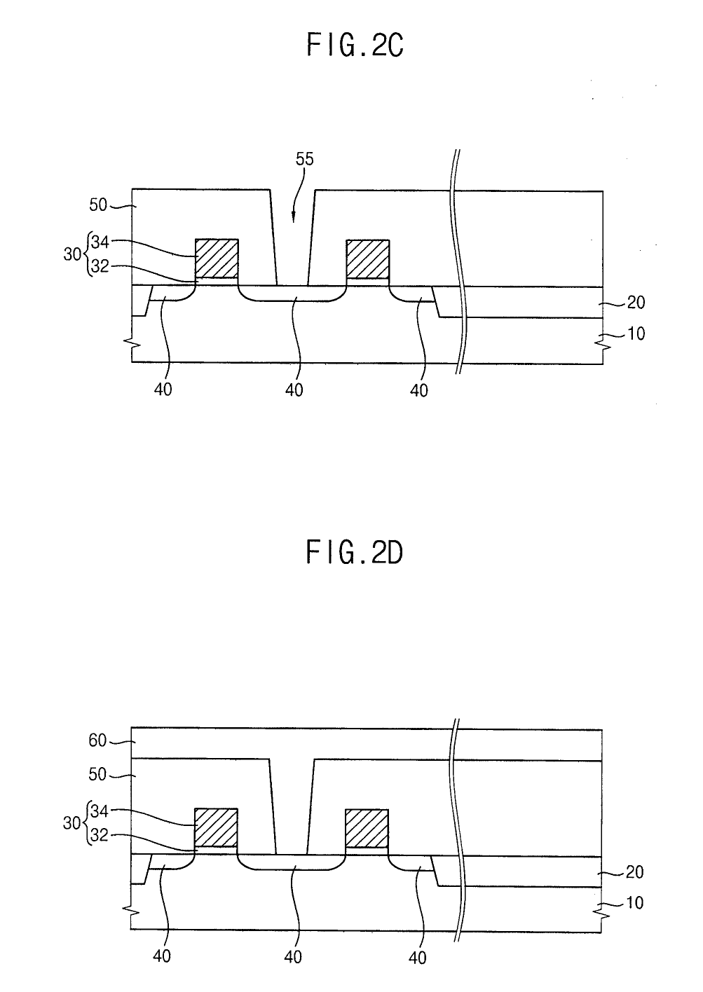

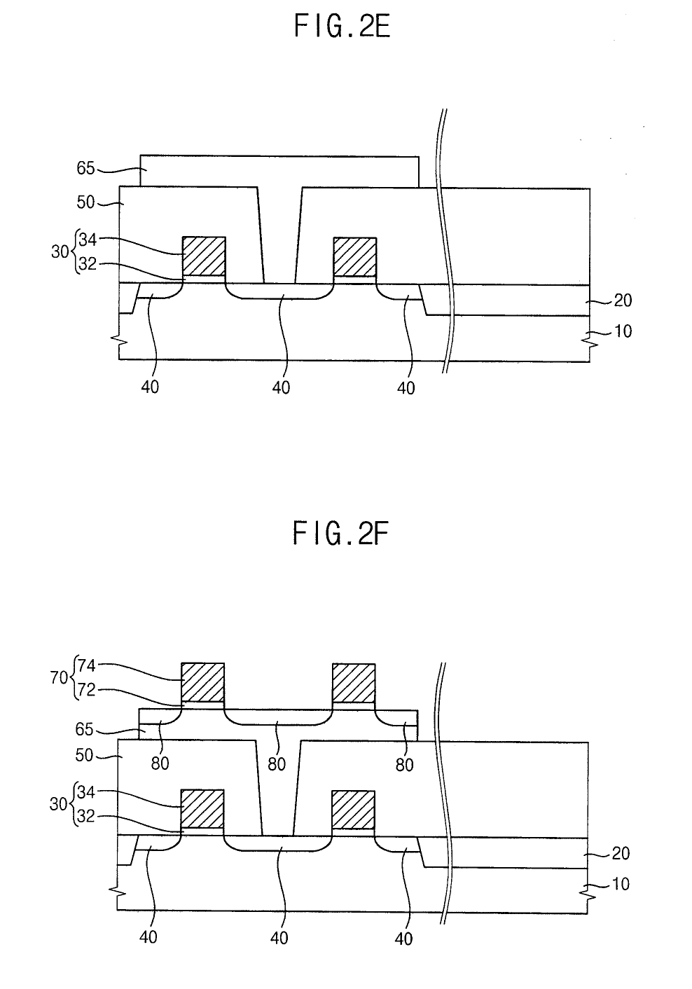

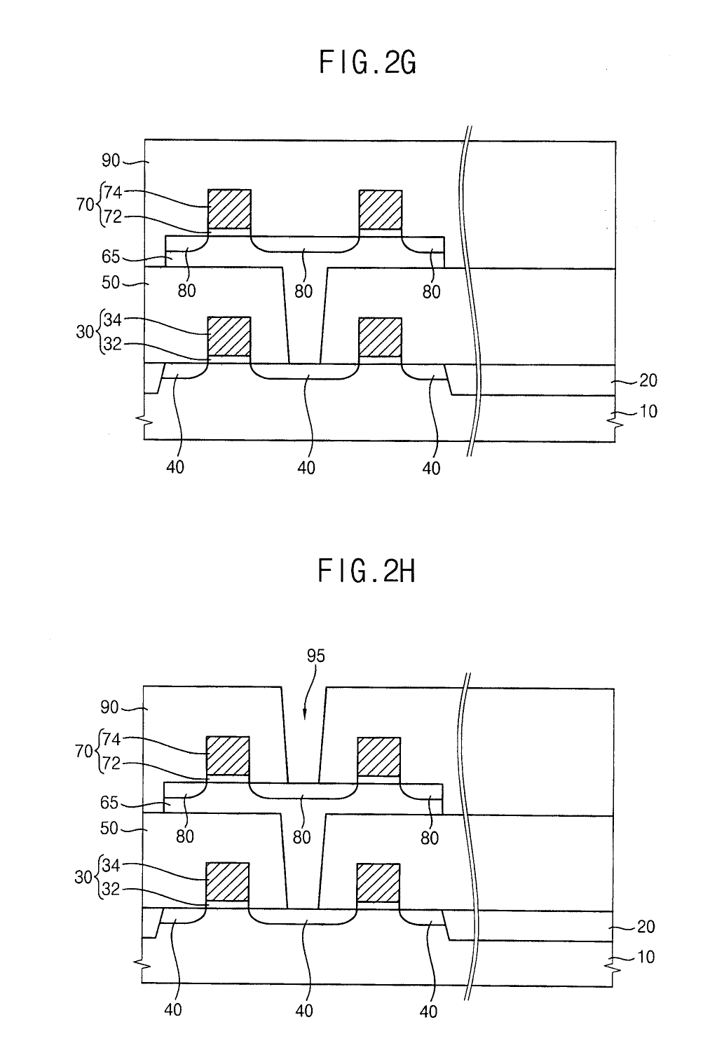

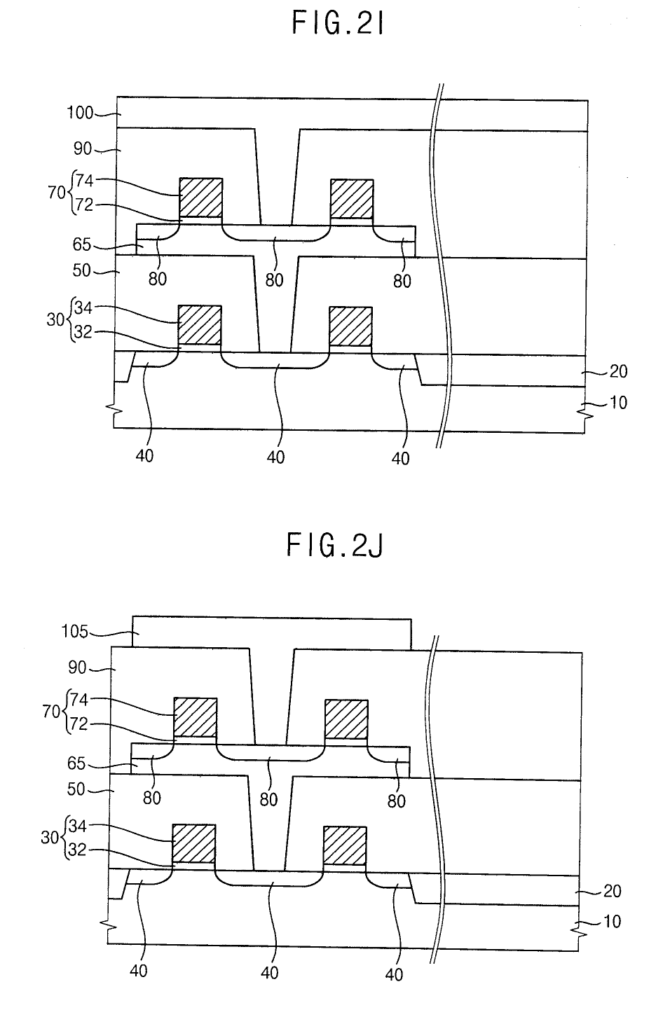

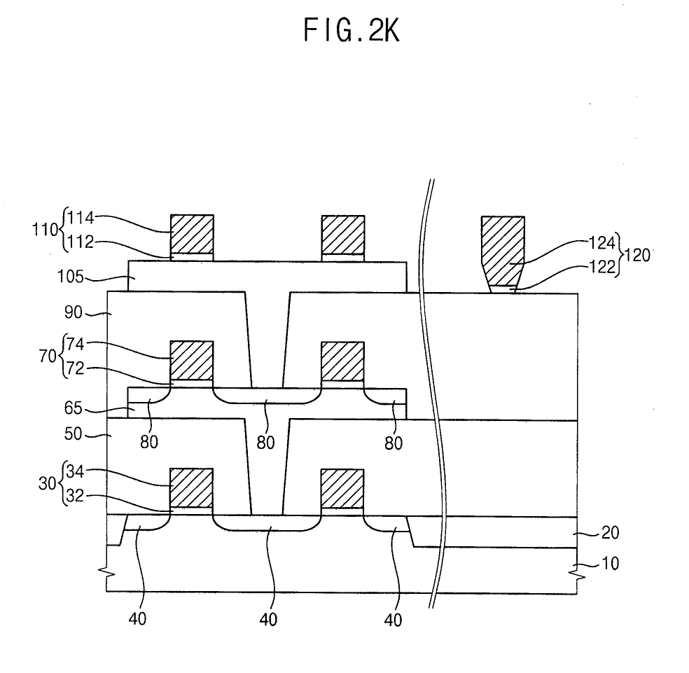

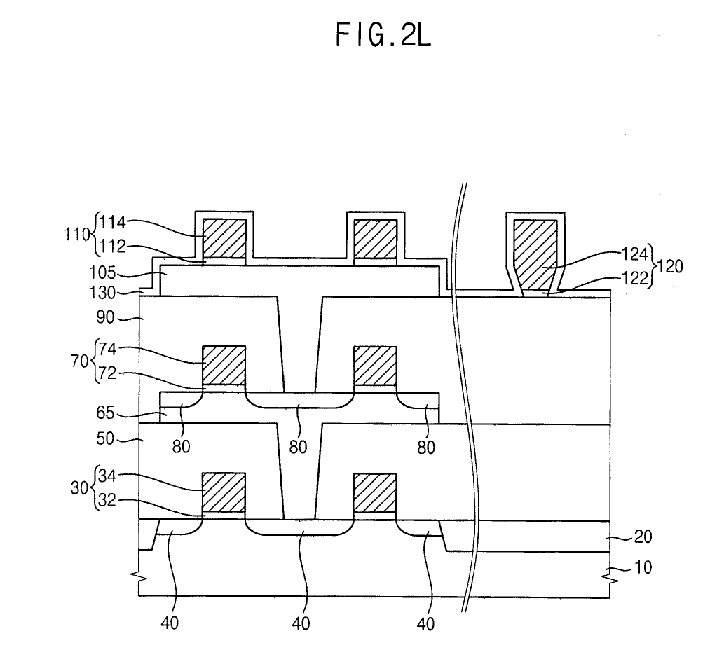

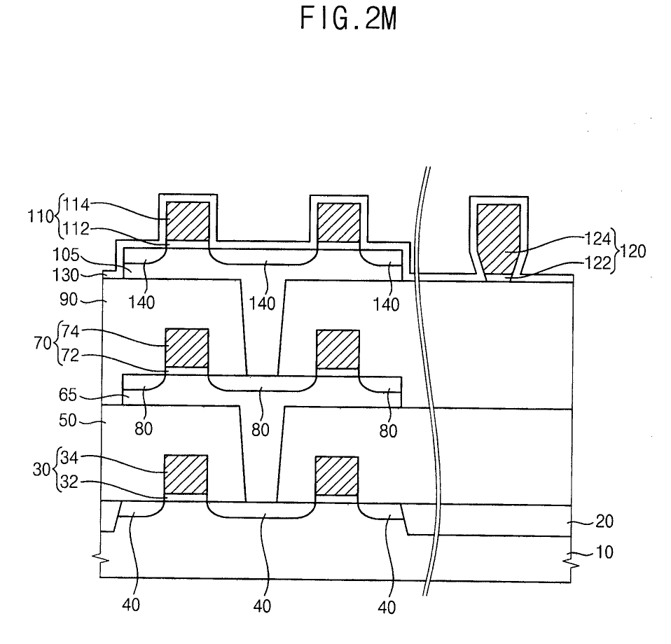

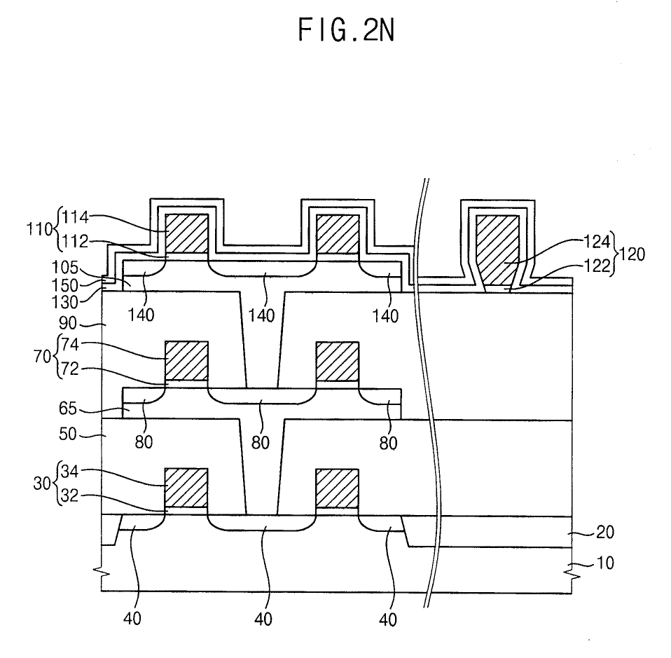

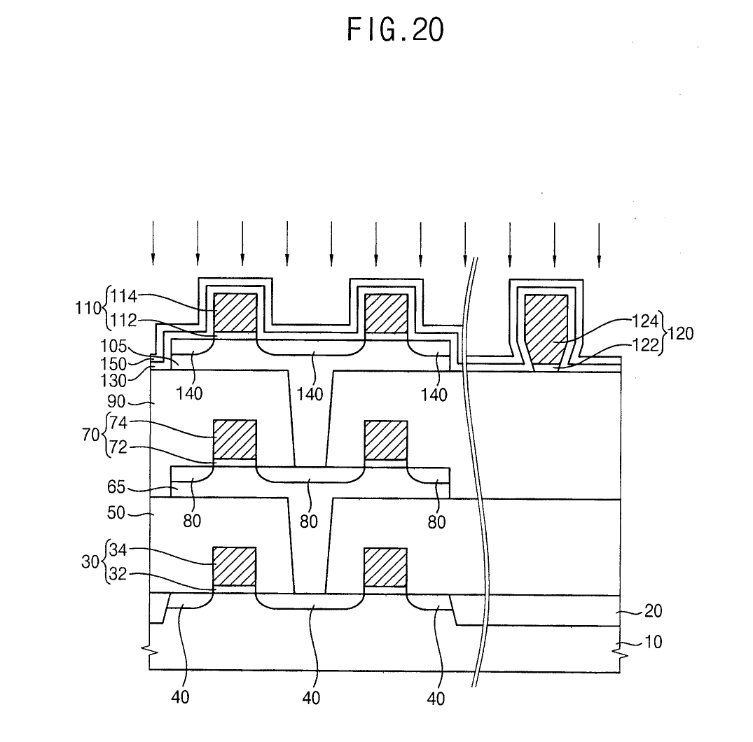

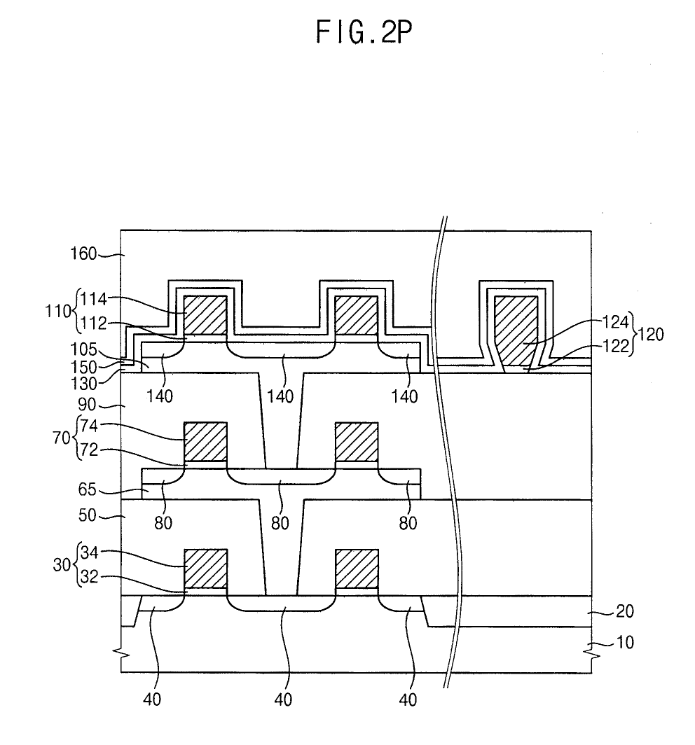

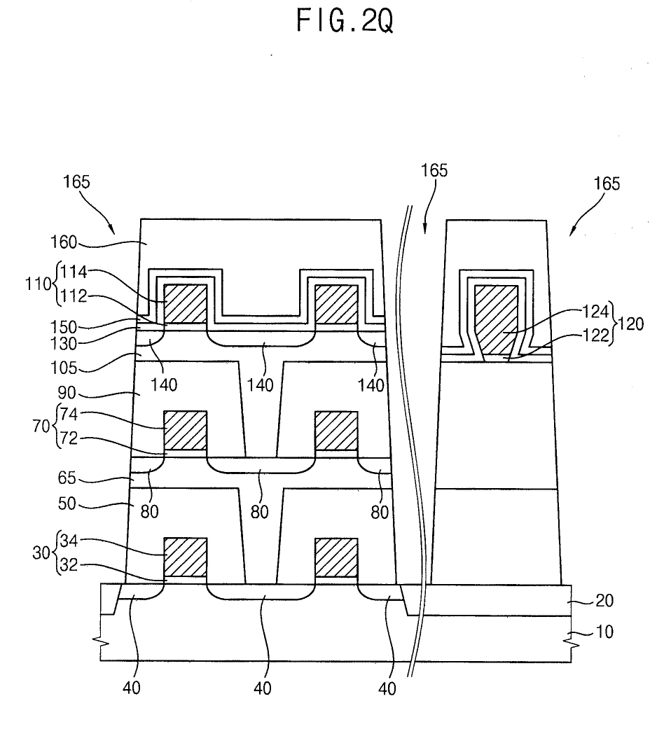

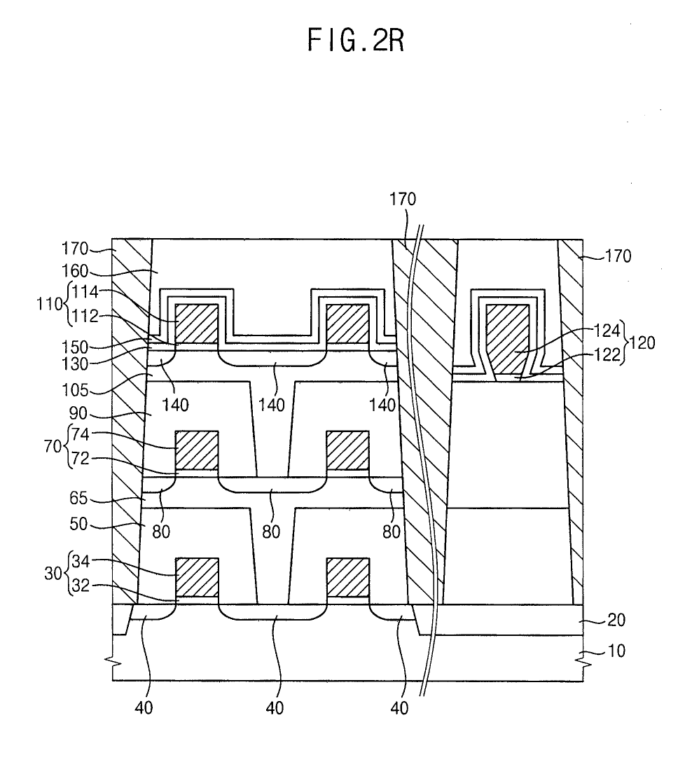

FIGS. 2A to 2R are cross-sectional views illustrating an embodiment of a method of manufacturing a stacked semiconductor device in accordance with some aspects of the present invention.

Referring to FIG. 2A, a substrate 10 is prepared. The substrate 10 can include a silicon substrate, a SOI substrate, a germanium substrate, a GOI substrate, a silicon-germanium substrate, and other such substrates known in the art.

An isolation layer 20 is formed on an upper portion of the substrate 10 to define a first active region and a first field region. In an example embodiment, the isolation layer 20 is formed by a shallow trench isolation (STI) process.

Particularly, after a pad oxide layer (not shown) and a pad nitride layer (not shown) are formed on the substrate 10, the pad oxide layer and the pad nitride layer are patterned by a photolithography process using a photoresist pattern (not shown) to form a pad oxide layer pattern (not shown) and a pad nitride layer pattern (not shown).

The substrate 10 is partially removed by an etching process using the pad oxide layer pattern and the pad nitride layer pattern as an etching mask so that a trench (not shown) is formed on the substrate 10.

A preliminary isolation layer (not shown) is formed on the substrate 10 having the pad oxide layer pattern and the pad nitride layer pattern to sufficiently fill up the trench. The preliminary isolation layer can be formed by a chemical vapor deposition (CVD) process or a plasma enhanced CVD (PE-CVD) process using a material having good fluidity characteristics, such as SOG, USG, HDP-CVD oxide, and other similar materials known in the art.

The preliminary isolation layer is partially removed until the pad nitride layer pattern is exposed so that a top surface of the preliminary isolation layer can be planarized. The pad nitride layer pattern and the pad oxide layer pattern are removed so that an isolation layer 20 filling the trench can be formed.

A first gate insulation layer and a first conductive layer are formed on the substrate 10 on which the isolation layer 20 is formed. The first gate insulation layer can be formed by an atomic layer deposition (ALD) process using a metal oxide that has a low EOT and low leakage current characteristics. The first gate conductive layer can be formed using polysilicon, a metal, or a metal oxide. In an example embodiment, the first gate conductive layer is formed by a CVD process using a metal oxide.

After forming a photoresist pattern (not shown) on the first gate insulation layer and the first conductive layer, the first gate insulation layer and the first conductive layer are partially removed by an etching process using the photoresist pattern as an etching mask to form a first gate structure 30 including a first gate insulation layer pattern 32 and a first gate electrode 34 sequentially formed on the substrate 10. The photoresist pattern can be removed by an ashing process and/or a stripping process.

First impurities are implanted into the first active region using the first gate structure 30 as an ion implantation mask so that a first source/drain region 40 is formed at an upper portion of the substrate 10 adjacent to the first gate structure 30. In an example embodiment, elements in Group V of the periodic table, such as phosphorus, arsenic, and other such elements known in the art are used as the first impurities, and thus the first source/drain region 40 can be an N-type impurity region. Accordingly, a first transistor including the first gate structure 30 and the first source/drain region 40 can be an N-type MOS transistor. In an example embodiment, two first transistors are formed in a unit cell, and each of the two first transistors can serve as a drive transistor.

A spacer (not shown) can be further formed on a sidewall of the first gate structure 30 using a nitride, such as silicon nitride. When the spacer is formed, the first source/drain region 40 can have an LDD structure.

Referring to FIG. 2B, a first insulating interlayer 50 is formed on the substrate 10 to cover the first gate structure 30. The first insulating interlayer 50 can be formed using an oxide, such as BPSG, USG, SOG, and other similar materials known in the art. In an example embodiment, the first insulating interlayer 50 is formed by a CVD process.

Referring to FIG. 2C, a first opening 55 is formed through the first insulating interlayer 50 to partially expose the substrate 10. In an example embodiment, the first opening 55 partially exposes the first source/drain region 40. The first opening 55 can be formed by a photolithography process in which the first insulating interlayer 50 is partially removed using a photoresist pattern (not shown) as an etching mask.

Referring to FIG. 2D, a first active layer 60 is formed on the substrate 10 and the first insulating interlayer 50 to fill up the first opening 55. In an example embodiment of the present invention, the first active layer 60 is formed by a selective epitaxial growth (SEG) process using the substrate 10 as a seed layer. The first active layer 60 can be formed on the first insulating interlayer 50 by an epitaxial lateral overgrowth (ELO) process.

The first active layer 60 can include single crystalline silicon, single crystalline germanium, single crystalline silicon-germanium, and other similar materials known in the art, according to a material of the substrate 10. In an example embodiment, the first active layer 60 including single crystalline silicon is formed by providing a silicon source gas, such as silane gas or disilane gas, for the substrate 10 at a temperature of about 600° C. to about 1,100° C.

Referring to FIG. 2E, the first active layer 60 is partially removed by a photolithography process using a photoresist pattern (not shown) as an etching mask to form a first active pattern 65. The first active layer 60 is partially removed to form the first active pattern 65 by the photolithography process so that a second active region in which the first active pattern 65 is formed and a second field region in which the first active pattern 65 is not formed can be defined, because directly forming an isolation layer on the active layer 60 is not easy.

Referring to FIG. 2F, similar to forming the first gate structure 30 with reference to FIG. 2A, after forming a second gate structure 70 including a second gate insulation layer pattern 72 and a second gate electrode 74 sequentially formed on the first active pattern 65, a second source/drain region 80 is formed at an upper portion of the first active pattern 65 adjacent to the second gate structure 70.

Particularly, after forming a second gate insulation layer and a second gate conductive layer on the first insulating interlayer 50 on which the first active pattern 65 is formed, the second gate insulation layer and the second gate conductive layer are patterned to form the second gate insulation layer pattern 72 and the second gate electrode 74. A protection layer (not shown) can be further formed on the first active pattern 65 on which the second gate structure 70 is formed and the first insulating interlayer 50, so that damages of the first active pattern 65 can be prevented from being generated when an ion implantation process is successively performed. Second impurities are implanted into the first active pattern 65 using the second gate structure 70 as an ion implantation mask so that the second source/drain region 80 can be formed at the upper portion of the first active pattern 65 adjacent to the second gate structure 70. In an example embodiment, elements in Group III of the periodic table such as boron, gallium, and other such elements known in the art are used as the second impurities, and thus the second source/drain region 80 can be a P-type impurity region. Accordingly, a second transistor including the second gate structure 70 and the second source/drain region 80 can be a P-type MOS transistor. In an example embodiment, two second transistors are formed in the unit cell, and each of the two second transistors can serve as a load transistor.

A spacer (not shown) including a nitride, such as silicon nitride, can be further formed on a sidewall of the second gate structure 70. When the spacer is formed, the second source/drain region 80 can have an LDD structure.

Referring to FIG. 2G, a second insulating interlayer 90 is formed on the first insulating interlayer 50 to cover the second gate structure 70 and the first active pattern 65. The second insulating interlayer 90 can be formed using a material substantially the same as that of the first insulating interlayer 50. Alternatively, the second insulating interlayer 90 can be formed using a material different from that of the first insulating interlayer 50. As examples, the second insulating interlayer 90 can be formed using BPSG, USG, SOG, and other similar materials known in the art. In an example embodiment, the second insulating interlayer 90 is formed by a CVD process.

Referring to FIG. 2H, a second opening 95 partially exposing the first active pattern 65 is formed through the second insulating interlayer 90. In an example embodiment, the second opening 95 partially exposes the second source/drain region 80. The second insulating interlayer 90 is partially removed by a photolithography process using a photoresist pattern (not shown) as an etching mask, so that the second opening 95 can be formed.

Referring to FIG. 2I, a second active layer 100 is formed on the first active pattern 65 and the second insulating interlayer 90 to fill up the second opening 95. In an example embodiment, the second active layer 100 is formed by an SEG process using the first active pattern 65 as a seed layer. The second active layer 100 can be formed on the second active layer 90 by an ELO process.

The second active layer 100 can include single crystalline silicon, single crystalline germanium, single crystalline silicon-germanium, and other similar materials known in the art, according to a material of the first active pattern 65. In an example embodiment, the second active layer 100 including single crystalline silicon is formed by providing a silicon source gas, such as silane gas or disilane gas, for first active pattern 65 at a temperature of about 600° C. to about 1,100° C.

Referring to FIG. 2J, the second active layer 100 is partially removed by a photolithography process using a photoresist pattern (not shown) as an etching mask to form a second active pattern 105, and thus a third active region and a third field region are defined.

Referring to FIG. 2K, similar to forming the first gate structure 30 with reference to FIG. 2A, a third gate structure 110 is formed including a third gate insulation layer pattern 112 and a third gate electrode 114 sequentially formed on the second active pattern 105. Additionally, a fourth gate structure 120 including a fourth gate insulation layer pattern 122 and a fourth gate electrode 124 sequentially formed on the second insulating interlayer 90, i.e., in the third field region, is formed. The fourth gate structure 120 is formed to be connected to the third gate structure 110. That is, the fourth gate structure 120 is also formed on the second insulating interlayer 90 on which the second active pattern 105 is not formed so that the third and fourth gate structures 110 and 120 each having a linear shape can serve as a word line.

Particularly, a third gate insulation layer and a third gate conductive layer are formed on the second insulating interlayer 90 on which the second active pattern 105 is formed. In an example embodiment, the third gate insulation layer is formed to have substantially the same thickness on the second active pattern 105 and the second insulating interlayer 90. However, the third gate conductive layer can be formed to have a larger thickness on the second insulating interlayer 90 than that on the second active pattern 105. That is, the third gate conductive layer can be formed to have a predetermined height from the second insulating interlayer 90. Accordingly, the third gate conductive layer can have a larger thickness on the second insulating interlayer 90, on which the second active pattern 105 is not formed, than the third gate conductive layer has on the second active pattern 105.

The third gate insulation layer can be formed using an oxide, such as a metal oxide. In an example embodiment, the third gate insulation layer is formed by an ALD process using a metal oxide. The third gate conductive layer can be formed using polysilicon, a metal, a metal nitride, and other similar materials known in the art. In an example embodiment, the third gate conductive layer is formed by a CVD process using a metal nitride.

After forming a photoresist pattern (not shown) on the third gate insulation layer and the third gate conductive layer, the third gate insulation layer and the third gate conductive layer are patterned by a photolithography process using the photoresist pattern as an etching mask to form a third gate structure 110 and a fourth gate structure 120. The third gate structure 110 can include a third gate insulation layer pattern 112 and a third gate electrode 114 sequentially formed on the second active pattern 105. The fourth gate structure 120 can include a fourth gate insulation layer pattern 122 and a fourth gate electrode 124 sequentially formed on the second insulating interlayer 90. The third gate structure 110 is formed to have a substantially vertical profile with respect to the second active pattern 105 so that a length of a channel region at an upper portion of the second active pattern 105 can have a predetermined value, because the length of the channel region depends on a width of the third gate structure 110. Accordingly, a lower portion of the fourth gate structure 120 can be sufficiently etched so that the fourth gate structure 120 can have an over-etched lower portion. The photoresist pattern can then be removed.

Referring to FIG. 2L, a protection layer 130 is formed on the second active pattern 105 and the second insulating interlayer 90 on which the third and fourth gate structures 110 and 120 are formed, respectively. The protection layer 130 can be formed to reduce damages of the second active pattern 105 generated when an ion implantation process is successively performed. In an example embodiment, the protection layer 130 is formed to have a thickness of about 100 Å on the second active pattern 105 and the second insulating interlayer 90 by a CVD process using an oxide. Additionally, prior to forming the protection layer 130, a gate oxide layer (not shown) can be further formed on the second active pattern 105 and the second insulating interlayer 90 in order to cure damages of the second active pattern 105 generated when the third gate structure 110 is formed.

Referring to FIG. 2M, third impurities are implanted into the second active pattern 105 using the third gate structure 110 as an ion implantation mask so that the third source/drain region 140 can be formed at the upper portion of the second active pattern 105 adjacent to the third gate structure 110. When the third impurities are implanted into the second active pattern 105, some portions of the third impurities can be implanted into the protection layer 130 and trapped therein. Thus, insulation characteristics of the protection layer 130 can be degenerated. In an example embodiment, elements in Group V of the periodic table, such as phosphorus, arsenic, and other such elements known in the art are used as the third impurities, and thus the third source/drain region 80 can be an N-type impurity region. Accordingly, a third transistor including the third gate structure 110 and the third source/drain region 140 can be an N-type MOS transistor. In an example embodiment, two third transistors are formed in the unit cell, and each of the two third transistors can serve as an access transistor.

Referring to FIG. 2N, a buffer layer 150 is formed on the protection layer 130. The buffer layer 150 can be formed using a material having good gap filling characteristics, such as SOG, USG, HDP-CVD oxide, and other similar materials known in the art, or a material having good insulation characteristics, such as ALD oxide, MTO oxide, and other similar materials known in the art. The buffer layer 150 can be formed by a CVD process or a PE-CVD process. In an example embodiment, the buffer layer 150 is formed to have a thickness of about 300 Å to about 1000 Å.

The buffer layer 150 formed on the protection layer 130 can prevent the portions of the third impurities trapped in the protection layer 130 from diffusing outward. Additionally, the buffer layer 150 can reduce or prevent voids from being generated near a lower portion of the fourth gate structure 120 when a third insulating interlayer 160 (see FIG. 2P) is formed. Furthermore, when a contact plug 170 (see FIG. 2R) is formed, a metal included in the contact plug 170 can be prevented from moving to the voids and making contact with the protection layer 130, so that degeneration of electrical insulation characteristics between the contact plug 170 and the fourth gate structure 120 can be prevented.

Referring to FIG. 20, a rapid thermal annealing (RTA) process is performed on the substrate 10 over which the second active pattern 105 and the buffer layer 150 are formed. The RTA process can be performed for a short time, such as several seconds, in order not to damage the second active pattern 105. Thus, the third impurities implanted into the second active pattern 105 can widely diffuse in the second active pattern 105 so that the third source/drain region 140 can have a wider distribution. Additionally, the buffer layer 150 can have a denser crystalline structure.

Alternatively, the RTA process can be performed before the buffer layer is formed. In this case, the RTA process can only help the third impurities implanted into the second active pattern 105 to diffuse in the second active pattern 105 so that the third source/drain region 140 can have a wider distribution.

Referring to FIG. 2P, the third insulating interlayer 160 is formed on the buffer layer 150. The third insulating interlayer 160 can be formed using BPSG, USG, SOG, and other similar materials known in the art. The third insulating interlayer 160 can be formed using a material substantially the same as that of the second and third insulating interlayers 50 and 90. Alternatively, the third insulating interlayer 160 can be formed using a material different from that of the first and second insulating interlayers 50 and 90. In an example embodiment, the third insulating interlayer 160 is formed by a CVD process.

Referring to FIG. 2Q, a third opening 165 partially exposing the substrate 10 is formed through the first to third insulating interlayers 50, 90 and 160, the buffer layer 150, the protection layer 130 and the first and second active patterns 65 and 105. In an example embodiment, the third opening 165 partially exposes the first source/drain region 40 and the isolation layer 20. The first to third insulating interlayers 50, 90 and 160, the buffer layer 150, the protection layer 130 and the first and second active patterns 65 and 105 are partially removed by a photolithography process using a photoresist pattern (not shown) as an etching mask, so that the third opening 165 can be formed.

Referring to FIG. 2R, a conductive layer is formed on the substrate 10 and the third insulating interlayer 160 to fill up the third opening 165. The conductive layer can be formed using a metal, such as tungsten, having good gap filling characteristics. The conductive layer can be formed by a CVD process, an ALD process or a sputtering process. Prior to forming the conductive layer, a barrier conductive layer (not shown) can be formed using a metal such as titanium or a metal nitride such as titanium nitride. The contact plug 170 filling the third opening 165 can be formed by planarizing the conductive layer. In an example embodiment, each of the first to third source/drain regions 40, 80 and 140 is electrically connected to one another via the contact plug 170. Particularly, the first and second drain regions and the third source region can be electrically connected to one another via the contact plug 170.

The stacked semiconductor device including the drive transistor, a load transistor and an access transistor can be completed by performing the above-described method.

Up to now, a semiconductor device having a triple-layered structure has been illustrated, however, any stacked semiconductor devices having a multi-layered structure can be formed by the above-described method. That is, when a transistor including a gate structure, which is extended in a direction and forms a word line, is formed on an active pattern and an insulating interlayer, voids can be generated near a lower portion of the gate structure because of the height difference between the active pattern and the insulating interlayer. In that case, insulation characteristics between the gate structure and a contact plug can be kept by forming a protection layer covering the gate structure.

According to some example embodiments, a buffer layer is formed on a gate structure serving as a word line in a stacked semiconductor device, so that voids generated near a lower portion of the gate structure having been over-etched on a field region because of the height difference between an active region and the field region can be reduced or prevented. Additionally, a metal included in a contact plug electrically connecting transistors formed in a plurality of layers can be prevented from moving to the voids so that insulation characteristics between the contact plug and the word line are not degenerated.

Furthermore, when the stacked semiconductor device includes a protection layer on an active pattern, a buffer layer formed on the protection layer can prevent impurities trapped in the protection layer from diffusing outward, so that insulation characteristics between the contact plug and the word line are not degenerated.

The foregoing is illustrative of aspects of the present invention and is not to be construed as limiting thereof. Although a few example embodiments have been described, those skilled in the art will readily appreciate that many modifications are possible in the example embodiments without materially departing from the novel teachings and advantages of the present invention. Accordingly, all such modifications are intended to be included within the scope of the present invention, as defined in the claims.

In the claims, means-plus-function clauses are intended to cover the structures described herein as performing the recited function and not only structural equivalents but also equivalent structures. Therefore, it is to be understood that the foregoing is illustrative of the present invention and is not to be construed as limited to the specific example embodiments disclosed, and that modifications to the disclosed example embodiments, as well as other example embodiments, are intended to be included within the scope of the appended claims. The present invention is defined by the following claims, with equivalents of the claims to be included therein.

What is claimed is:

1. A semiconductor device comprising:
a first gate structure on a substrate;
a first insulating interlayer covering the first gate structure on the substrate;
a first active pattern formed through and on the first insulating interlayer, the first active pattern making contact with the substrate;
a second gate structure on the first active pattern and the first insulating interlayer;
a buffer layer covering the second gate structure on the first active pattern and the first insulating interlayer;
a second insulating interlayer on the buffer layer; and
a contact plug formed through the first and second insulating interlayers, the contact plug configured to make contact with the substrate and to be insulated from the second gate structure by the buffer layer.

2. The semiconductor device of claim 1, wherein the second gate structure includes a third gate structure on the first active pattern and a fourth gate structure on the first insulating interlayer.

3. The semiconductor device of claim 2, wherein the third and fourth gate structures are connected to form a word line.

4. The semiconductor device of claim 3, wherein the third gate structure has a substantially vertical profile with respect to the first active pattern, and the fourth gate structure has a lower portion narrower than an upper portion thereof.

5. The semiconductor device of claim 1, wherein the first gate structure includes a first gate insulation layer pattern and a first gate electrode, and the second gate structure includes a second gate insulation layer pattern and a second gate electrode.

6. The semiconductor device of claim 1, wherein the substrate includes an active region and a field region, the active region having a first source/drain region, the first active pattern making contact with the first source/drain region.

7. The semiconductor device of claim 6, wherein the first active pattern includes a second source/drain region, and the contact plug is electrically connected to the first and second source/drain regions.

8. The semiconductor device of claim 1, wherein the buffer layer comprises a material selected from the group consisting of spin-on-glass (SOG), undoped silicate glass (USG), high density plasma chemical vapor deposition (HDP-CVD) oxide, atomic layer deposition (ALD) oxide, and middle temperature oxide (MTO).

9. The semiconductor device of claim 1, further comprising a protection layer formed between the first active pattern and the first insulating interlayer, the protection layer configured to prevent damage to the first active pattern.

10. The semiconductor device of claim 1, wherein the substrate includes silicon and the first active pattern includes single crystalline silicon.

11. A semiconductor device comprising:
a first gate structure on a substrate;
a first insulating interlayer covering the first gate structure on the substrate;
a first active pattern formed through and on the first insulating interlayer, the first active pattern making contact with the substrate;
a second gate structure on the first active pattern;
a second insulating interlayer covering the second gate structure on the first active pattern and the first insulating interlayer;
a second active pattern formed through and on the second insulating interlayer, the second active pattern making contact with the first active pattern;
a third gate structure on the second active pattern and the second insulating interlayer;
a buffer layer covering the third gate structure on the second active pattern and the second insulating interlayer;
a third insulating interlayer on the buffer layer; and
a contact plug formed through the first to third insulating interlayers, the contact plug being configured to make contact with the substrate and insulated from the third gate structure by the buffer layer.

12. The semiconductor device of claim 11, wherein the third gate structure includes a fourth gate structure on the second active pattern and a fifth gate structure on the second insulating interlayer, and the fourth and fifth gate structures are connected to form a word line.

13. The semiconductor device of claim 12, wherein the fourth gate structure has a substantially vertical profile with respect to the second active pattern, and the fifth gate structure has a lower portion narrower than an upper portion thereof.

14. The semiconductor device of claim 11, wherein the substrate includes an active region and a field region, the active region having a first source/drain region, and the first and second active patterns include second and third source/drain regions, respectively, and the contact plug is electrically connected to the first to third source/drain regions.

15. The semiconductor device of claim 14, wherein the first gate structure and the first source/drain region form a drive transistor, the second gate structure and the second source/drain region form a load transistor, and the third gate structure and the third source/drain region form an access transistor.
